(19) United States
(12) Patent Application Publication
(10) Pub. No.: US 2009/0152587 A1
(43) Pub. Date: Jun. 18, 2009

(54) DEEP GUARD REGIONS FOR REDUCING LATCH-UP IN ELECTRONICS DEVICES

(75) Inventors: Lorenzo CERATI, Cinisello Balsamo (MI) (IT); Luca CECCHETTO, Villadose (RO) (IT); Mariano DISSEGNA, Schio (VI) (IT)

Correspondence Address: GRAYBEAL JACKSON LLP, 155 - 108TH AVENUE NE, SUITE 350, BELLEVUE, WA, 98004-5973, US

(73) Assignee: STMICROELECTRONICS S.R.L., Agrate Brianza (IT)

(21) Appl. No.: 12/335,178

(22) Filed: Dec. 15, 2008

(30) Foreign Application Priority Data
Dec. 14, 2007 (IT) MI2007A002340

(51) Int. Cl. H01L 21/763; H01L 29/06; H01L 29/73

(52) U.S. Cl. 257/147; 438/524; 257/401; 257/E21.572; 257/E29.006; 257/E29.181

(57) ABSTRACT

An embodiment of an integrated circuit includes a semiconductor layer, a well, first and second source/drain regions, and a guard region. The semiconductor layer has a first conductivity, and the well is disposed in the layer and has a second conductivity. The first source/drain region is formed in the well and has the first conductivity, and the second source/drain region is formed in the layer outside of the well and has the second conductivity. The guard region is disposed in the layer between the well and the second source/drain region and has the second conductivity. The guard region may prevent latch up by inhibiting the triggering of a silicon-controlled rectifier (SCR) having one of the first and second source/drain regions as an anode and the other of the first and second source/drain regions as a cathode.

### RELATED APPLICATION DATA

This application is related to U.S. patent application Ser. No. ______ entitled DEEP CONTACTS OF INTEGRATED ELECTRONIC DEVICES BASED ON REGIONS IMPLANTED THROUGH TRENCHES (Attorney Docket No. 2110-294-03), which has a common filing date and which is incorporated by reference.

### PRIORITY CLAIM

This application claims priority from Italian patent application No. MI2007A002340, filed Dec. 14, 2007, which is incorporated herein by reference.

### TECHNICAL FIELD

An embodiment of the present invention relates to the electronics field. More specifically, an embodiment of the present invention relates to the reduction of latch-up phenomena in integrated circuits.

### BACKGROUND

The latch-up phenomenon (or simply latch-up) is a failure mechanism of an integrated circuit due to the switching on of a parasitic thyristor or SCR (Silicon Controlled Rectifier). The parasitic SCR is formed by two cross-coupled parasitic PNP and NPN BJTs (Bipolar Junction Transistors), which may cause an undesired over-current to flow through the integrated circuit until the destruction thereof.

In detail, a base region of the parasitic NPN BJT is cross-coupled with a collector region of the parasitic PNP BJT, so that a current flowing through one of the two parasitic BJTs turns on the other parasitic BJT. This activates a regenerative feedback that causes a progressive increment of the current.

The parasitic BJTs may be formed by any diffused or implanted regions used for implementing one or more electronic components of the integrated circuit (for example, in CMOS circuits).

The latch-up depends on several factors. For example, the switching on of the parasitic SCR is a function of a current gain of the parasitic BJTs, and then of their base width. Therefore, as the base width decreases, the switching on of the parasitic SCR occurs more easily. This is in contrast with the demand of increasing the device integration density. Indeed, with the scaling of the standard technologies, the size of the electronic components progressively reduces.

A classical solution for reducing the latch-up is based on the use of a guard (or protection) ring, as described in “Novel Technique o Reduce Latch-up Risk due to ESD Protection Devices in Smart Power Technologies”—L. Cerati, L. Cecchetto, M. Dissegna. A. Andreini, G. Ricotti, Proceeding of 2006 EOSESD Symposium, Tucson and in “Novel achievements in the understanding and suppression of parasitic minority carrier currents in P− epitaxy/P++substrate Smart Power Technologies”—R.-Stella. S. Favilla e G. Croce, Proceeding of 2004 International Symposium on Power Semiconductor Device & ICs, Kitakyushu, which are incorporated by reference. The guard ring includes a highly doped region that is arranged between the base region and the collector region of the parasitic NPN BJT; the guard region is usually biased to a power supply voltage. The guard ring collects minority carriers and limits the electron flow towards any other diffused region (of the N type), thus reducing the gain of the parasitic NPN BJT and thereby inhibiting the switching on of the parasitic SCR. However, the guard ring may sink a relatively high current (of the order to some hundreds of mA). Therefore, a large metallization strip may be required to contact the guard ring, with routing problems and waste of area, in any case, a large power consumption is usually involved.

An alternative solution includes the connection of the guard ring to a local substrate voltage. It has been demonstrated that the efficiency is not meaningfully impacted if relatively thin substrates (<10 μm) are considered, while routing and power consumption issues are greatly reduced.

In any case, the above-described solutions based on the guard ring may not be efficient when used in power applications, wherein power components (such as vertical MOS transistors) are housed in a relatively thick epitaxial layer stacked on a substrate—in order to sustain high voltages (such as, 50-150V). Indeed, the guard ring should reach depths (such as, 10-15 μm) substantially equal to the thickness of the epitaxial layer wherein the power components are formed, However, modern manufacturing processes (also known as “cold processes”) work at relatively low temperatures. A typical example is that of smart power applications, wherein the integrated circuit comprises other components, such as logic circuits controlling the power components (for example, a microprocessor, a digital signal processor), a memory module, power supply management circuits and circuits that enable the communication of the device with the outside. In this case, in order to improve the performance of the device, the doped regions exploited for implementing the electronic components are formed without any diffusion of the doping impurities in the epitaxial layer; conversely, short thermal processes (such as annealing processes) are used exclusively for activating the doping impurities, which have been previously implanted. Therefore, the cold processes do not allow obtaining the desired depth of the guard ring by diffusion (since it is performed at a too low temperature). The same problem is experienced when the guard ring is obtained by implantation, since the energy manageable by the implanting machines limits the depth that can be reached by the guard ring (typically, up to 4 μm). Therefore, below the implanted guard ring, a relatively thick layer (for example, of the P type) is present, where minority carriers may diffuse without being collected.

A different solution known in the art for reducing the latch-up, as described in U.S. Pat. No. 6,956,266, which is incorporated by reference, is instead based on the use of trenches. Particularly, the trenches extend into the region where the base of one of the parasitic BJTs forms, and are then coated with an insulating conforming layer and filled with polysilicon or dielectrical material (such as silicon dioxide), this increases the (effective) base width of the parasitic BJT so as to reduce its current gain.

More generally, the trenches are also used in different applications.

For example, U.S. Pat. No. 6,576,516, which is incorporated by reference, discloses a power MOSFET wherein the trenches are filled with a polysilicon layer, which is subsequently diffused in order to reduce an on-resistance of the power MOSFET.

U.S. Pat. No. 6,326,283, which is incorporated by reference, discloses a trench for forming STI regions. In particular, a multi-step method is proposed for reducing the sharp corners where a trench side wall joints a free surface of a chip in which the trench is formed.

U.S. Pat. No. 6,469,366, which is incorporated by reference, discloses a trench filled with polysilicon, which is exploited as an emitter/collector region of a BJT or as an isolation zone for insulating the electronic components that are integrated in a same chip.

U.S. Pat. No. 6,943,426, which is incorporated by reference, discloses a trench, filled with dielectric material, which is used for laterally limiting diffusion regions.

Finally, U.S. Pat. No. 6,870,222, which is incorporated by reference, discloses a method of manufacturing a high frequency device. In this case, the trenches are used for forming a substrate contact. In detail, the substrate contact includes diffused regions surrounding the trenches, which are filled with polysilicon, in particular, the diffused regions are formed by depositing doping impurities (such as Boron ions) and by diffusing them at high temperatures for a time sufficiently long to guarantee that the doping impurities reach a desired depth. In such a way doping impurities injections (that is, implantation processes) at high energy are not needed.

### SUMMARY

In principle, an embodiment of the present invention is based on the idea of using one or more trenches for implanting doping impurities deeply in order to reduce the latch up sensitivity.

In detail, an embodiment of the present invention is a method for reducing a latch-up phenomenon in an electronic device; the electronic device is integrated in a semiconductor chip, which has an exposed surface. The chip includes at least one parasitic lateral bipolar transistor with a base region. The method includes the step of forming a guard region, which extends from the exposed surface into the base region of each parasitic lateral bipolar transistor. For this purpose one or more trenches are formed. The trenches extend from the exposed surface into the base region; each trench has a lateral surface and a bottom surface. Doping impurities are implanted into the chip through at least part of the lateral surface of each trench. The trenches are filled with conductive material. The implanted doping impurities are then activated so as to obtain one or more surrounding regions around each trench.

In an embodiment of the method, the base region and the guard region are of opposite type of conductivity.

In an embodiment of the present invention, the base region is short circuited with the guard region.

For this purpose, it is possible to contact the filled trenches,

The doping impurities may also be implanted through the bottom surface of the trenches.

An embodiment of the method includes forming two or more trenches, which are embedded in a single surrounding region.

One or more corresponding beams of doping impurities may be inclined with respect to an axis of each trench.

In an embodiment of the inventions an annealing process is performed after filling the trenches.

Suggested annealing temperature and period are proposed.

Each trench may be deeper than larger.

In an embodiment of the present invention, a form ratio between a trench depth and a trench width ranges from 2 to 20.

Particularly, the conductive material may be polysilicon being doped in situ.

In an embodiment of the present invention, the chip of the semiconductor material includes an active layer stacked on a substrate (with the trenches that reach the substrate).

One or more CMOS pairs may be integrated in the active layer.

In an embodiment of the invention, power components are integrated in the chip.

The step of activating the doping impurities may be performed at the same time for the power components and the guard region.

Particularly, a logic circuit as well may be integrated in the chip.

Another embodiment of the present invention provides a corresponding electronic device obtained by an embodiment of the proposed method.

### BRIEF DESCRIPTION OF THE DRAWINGS

One or more embodiments of the present invention, as well as further features and the advantages thereof will be best understood by reference to the following detailed description, given purely by way of a non-restrictive indication, to be read in conjunction with the accompanying drawings. In this respect, it is expressly intended that the figures are not necessary drawn to scale and that, unless otherwise indicated, they are merely intended to conceptually illustrate the structures and procedures described herein. Particularly:

FIG. 1A is a cross-section view of an electronic device affected by the latch-up;

FIG. 1B illustrates an exemplificative electrical characteristic of a generic SCR;

FIG. 2 is a cross-section view of an electronic device including a guard region for reducing the latch-up, according to an embodiment of the present invention;

FIGS. 3A through 3G are cross-section views illustrating the main phases of the manufacturing process of an electronic device including a guard region, according to an embodiment of the present invention;

FIG. 4 shows exemplificative diagrams relating to simulated electrical operative parameters of an integrated electronic device including a guard region, according to an embodiment of the present invention.

### DETAILED DESCRIPTION

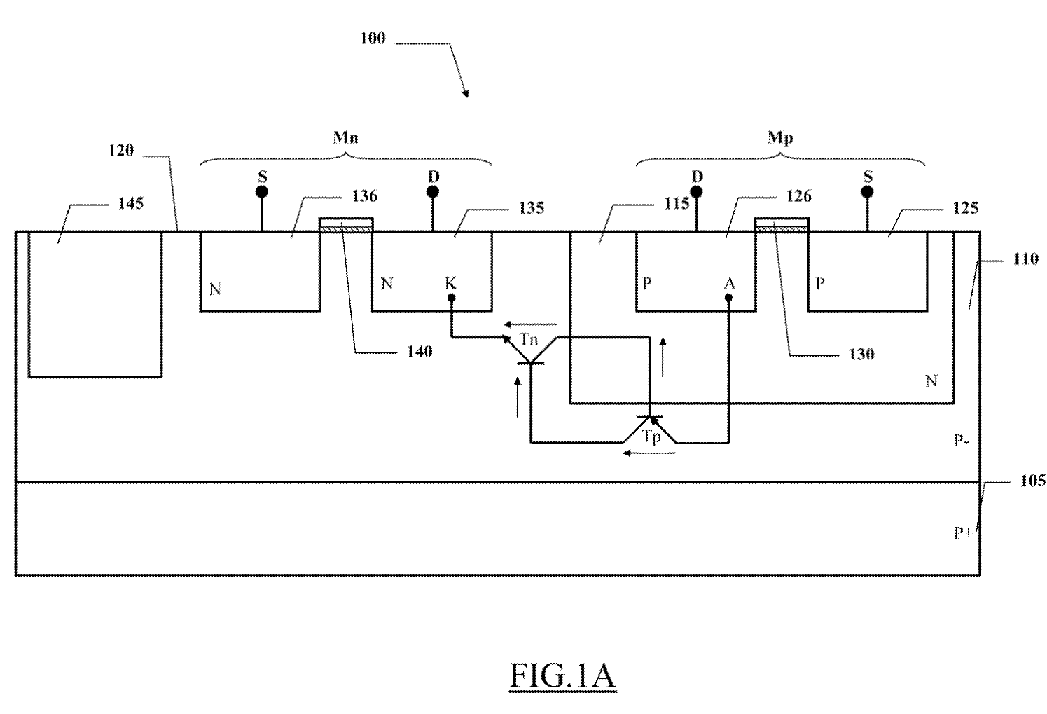

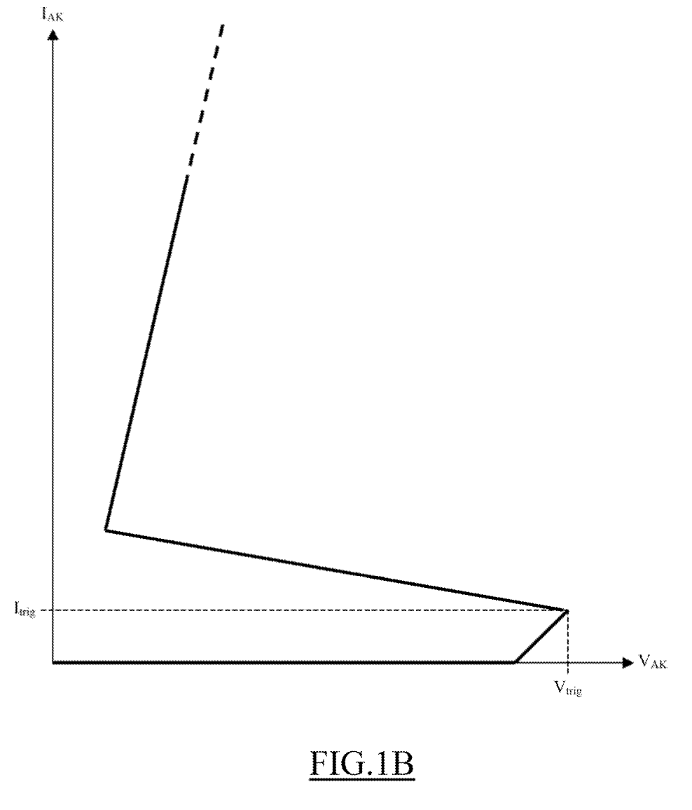

With reference now to the figures, FIG. 1A shows a cross-section view of an electronic device 100. As usual, the concentrations of N-type and P-type doping impurities are denoted by adding the sign + or the sign − to the letters N and P to indicate a high or low concentration of impurities, respectively, or the sign ++ or the sign −− to indicate a very high or a very low concentration of impurities, respectively; the letters N and P without the addition of any sign + or − denote concentrations of intermediate value.

In particular, the device 100 (for example, of the smart power type) is formed in a chip including a semiconductor substrate 105 (for example, of the P+ type). The electronic components of the device 100—either of the power type or of the logic type—are integrated in a semiconductor active layer 110 (for example, of the P− type), which is stacked on the substrate 105.

More specifically, the device 100 includes one or more power CMOS pairs (only one shown in the figure); each CMOS pair is formed by an n-channel MOS transistor Mn and a p-channel MOS transistor Mp.

Particularly, the MOS transistor Mp includes a well region 115 of the N-type, which extends into the active layer 110 from an exposed (or front) surface 120 thereof, A source (S) region 125 and a drain (D) region 126 of the P-type extend into the well region 115 from the front surface 120. An insulated gate 130 is arranged over the well region 115 between the source region 125 and the drain region 126; when the gate 130 is suitably biased, the underlying well region 115 inverts so as to form a channel of the P-type.

The MOS transistor Mn is instead formed by a drain (D) region 135 and a source (S) region 136 of the N-type, which extend into the active layer 110 from the front surface 120 (beside the well region 115). An insulated gate 140 is arranged over the active layer 110 between the drain region 135 and the source region 136; when the gate 140 is suitably biased, the underlying active layer 110 inverts so as to form a channel of the N-type.

The device 100 also includes logic circuits (generally denoted with 145), which are used to control the above-described power elements.

in this structure, a parasitic SCR—including a parasitic (NPN) BJT Tn and a parasitic (PNP) BJT Tp—is also formed. Particularly, the drain region 135 of the MOS transistor Mn acts as an emitter region of the parasitic BJT Tn—defining a cathode (K) of the SC Tn,Tp—while the active layer 110 acts as a base region of the parasitic BJT Tn and as a collector region of the parasitic BJT Tp. The well region 115 instead acts as a collector region of the parasitic BJT Tn and as a base region of the parasitic BJT Tp. Finally, the drain region 126 acts as an emitter region of the parasitic BJT Tp—defining an anode (A) of the SCR Tn,Tp. In occurrence of unexpected phenomena (such as thermal and over-voltage stresses, intense ionizing radiations, or transient voltage spikes causing capacitive displacement currents) the emitter-base junction of the parasitic BJT Tn may be forward biased so as to cause a current to flow through it. This current is extracted from the base region of the parasitic BJT Tp, so as to cause a current to flow through it as well. This current in turn is injected into the base region of the parasitic BJT Tn, so as to cause a further increase of its current.

When the following condition is satisfied:

β_{N}*β_{P}>1

(wherein β_{N} is the forward current gain of the parasitic BJT Tn and βₚ is the forward current gain of the parasitic BJT Tp), a regenerative feedback arises, with a progressive increment of the current.

As shown in FIG. LB, providing an exemplificative electrical characteristic of the parasitic SCR (plotting its current I_{AK} against its voltage V_{AK}—between the anode and the cathode thereof), the SCR is switched on after reaching a triggering voltage V_{trig} corresponding to a triggering current I_{trig}. Afterward, the current I_{AK} continues increasing even if the voltage V_{AK} reduces.

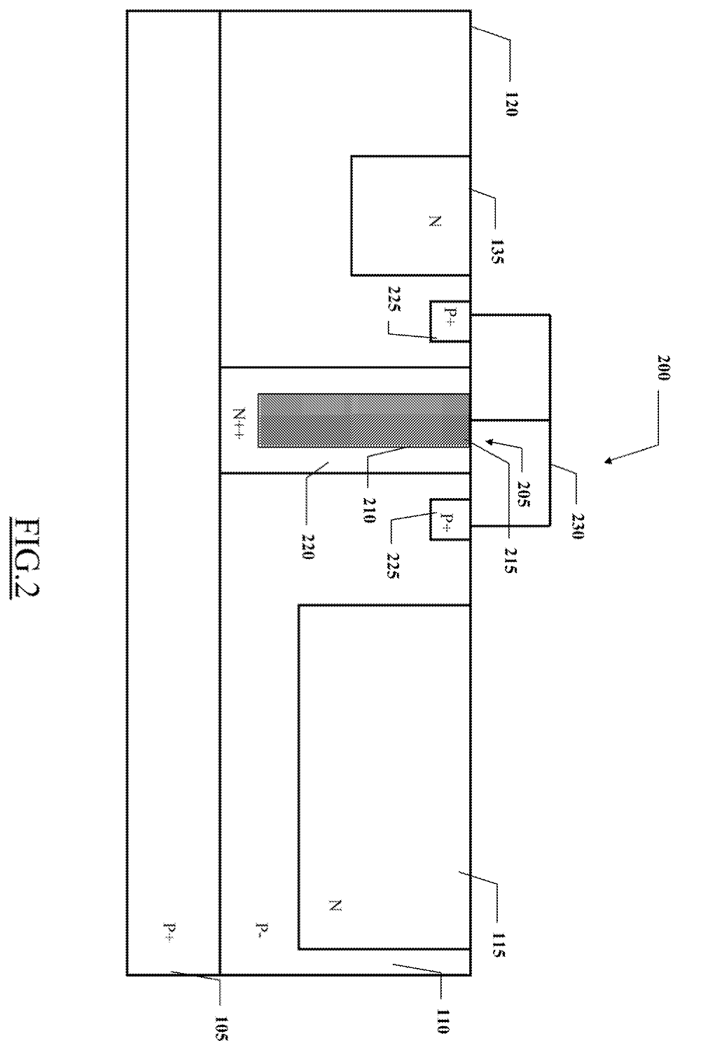

With reference now to FIG. 2, a cross-section view of an electronic device 200 according to an embodiment of the present invention is shown. In the following, elements corresponding to the ones of FIG. 1A will be indicated with the same references and their explanation will be omitted for the sake of brevity.

The device 200 includes a guard region 205 extending into the active layer 110 from the front surface 120; this guard region 205 is arranged between the two N-type regions 115 and 135 acting as the emitter region and the collector region, respectively, of the parasitic BJT Tn (for example, in the form of a ring around one of them). For the sake of simplicity, in the following description reference will be made only to the parasitic NPN BJT; however similar considerations apply to the parasitic PNP BJT.

According to an embodiment of the present invention, as described in detail in the following, the guard region 205 is formed by exploiting one or more trenches 210 (only one shown in figure) extending from the front surface 120 into the active layer 110.

For this purpose, doping impurities are implanted (and then activated) into the chip through at least part of a lateral surface of the trench 210 (which is then filled with conductive material 215). As a result, a highly doped surrounding region 220 (for example, of the N+ type) is obtained around the trench 210

In such a way, the doping impurities are placed deeply in the desired region of the active layer 110. During operation of the device 200, the substrate 105 (and the active layer 110) Is typically kept at a reference voltage (or ground). In this way, the guard region 205 (at ground as well) acts as an auxiliary collector adapted to collect any undesired current injected into the active layer 110 (that is, into the base region of the parasitic BJT at issue); this reduces the current gain of the parasitic BJT, and then the latchup. The efficiency of this embodiment relies on the ability of pinching the low-doped layer of the P type where the electrons may flow. The implantation of doping impurities deeply into the chip is therefore greatly beneficial to collect free carriers thus reducing the gain of the parasitic BJT. The desired result may be achieved without requiring any further diffusion of the doping impurities (apart from the ones already present in a standard process flow).

Thus, this embodiment allows increasing the depth of the guard region 205 (thereby increasing its efficiency in preventing the latch-up) at the same time maintaining the area on the front surface 120 wasted by it relatively small. It is emphasized that the trench 210 is primarily used to implant the doping impurities deeply, and only secondarily as a guard region; as a result, its size can be maintained as small as possible (just enough to form the surrounding region 220, which mainly defines the desired guard region 205).

All of the above may have a beneficial impact on the size of the whole device 200.

In an embodiment of the invention, two contact regions 225 of the P++type extend into the active layer 110 from the front surface 120 around the guard region 205, so as to define an ohmic contact for the active layer 110. A conductive path (represented schematically in the figure with a line 230) short-circuits the guard region 205 with the contact regions 225.

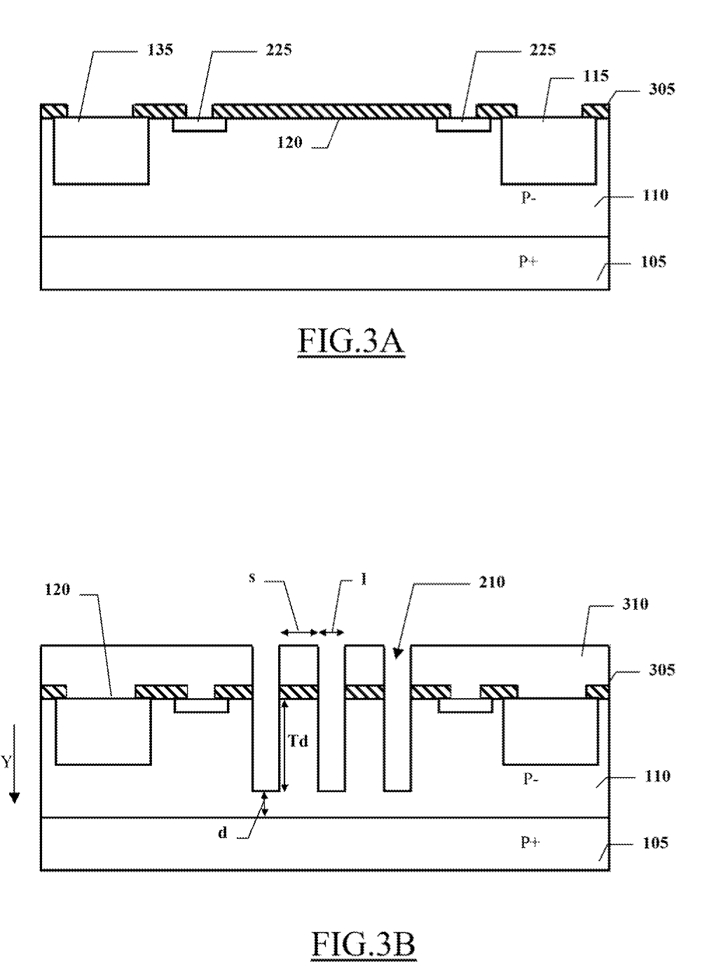

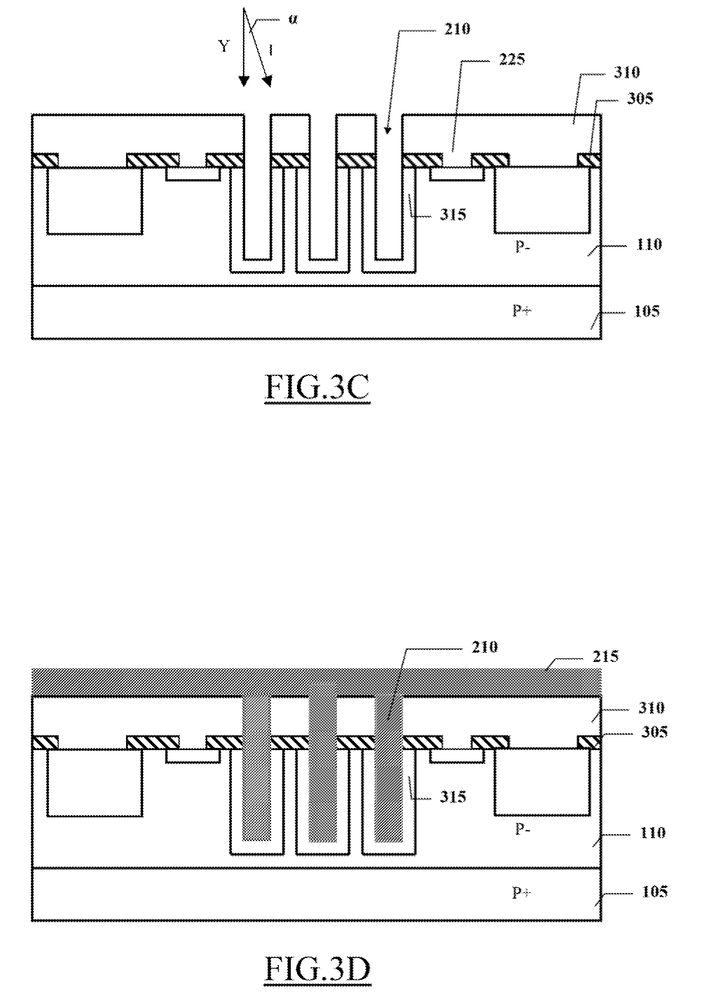

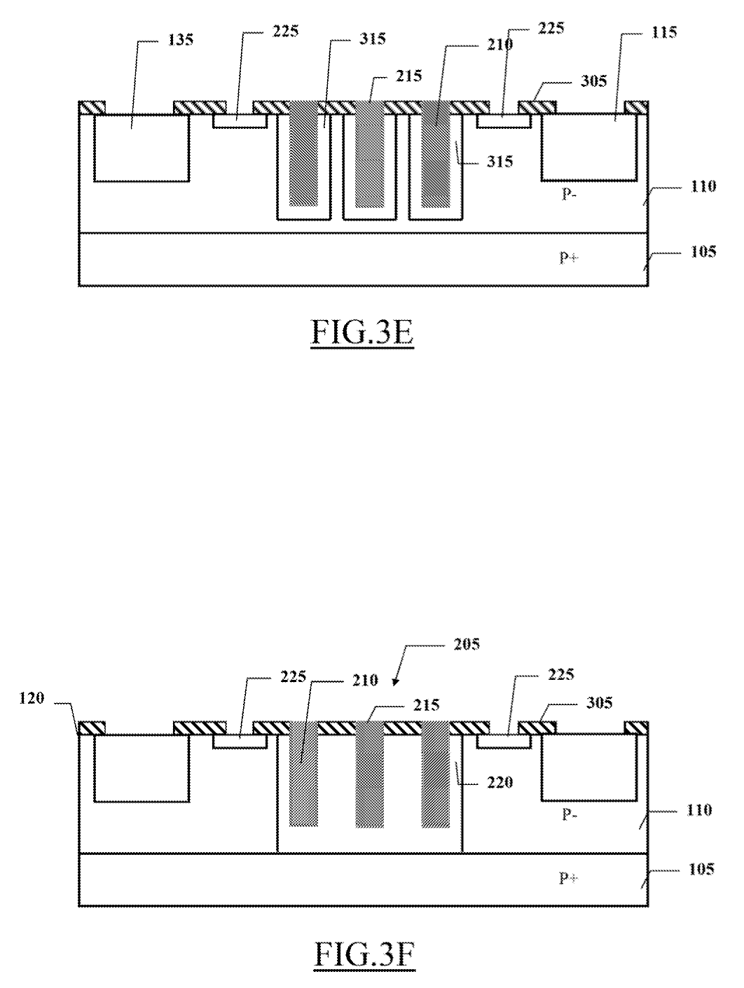

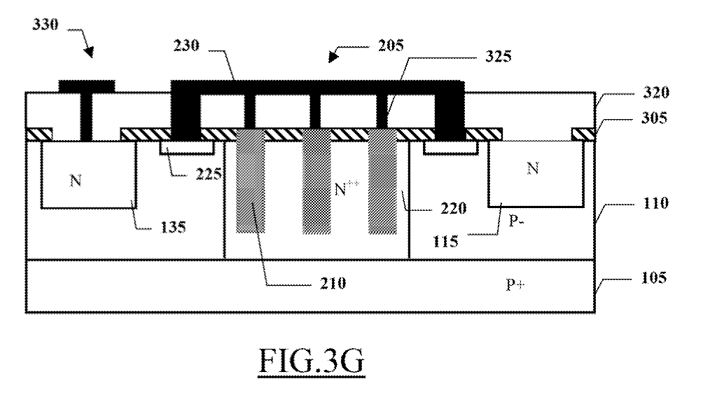

Referring now to FIGS. 3A through 3G, an embodiment of a process for manufacturing an embodiment of the electronic device is explained in detail.

Considering in particular FIG. 3A, the starting material is a wafer including the semiconductor substrate 105 (wherein a plurality of identical chips will be formed). For example, the substrate 105 (of the P+ type) has a dopant concentration ranging from 5*10¹⁸ to 5*10²⁰ ions/cm³. Moreover, the wafer includes the active layer 110 of the P⁻-type, which is generally formed by one or more epitaxial layers grown on the substrate 105; in the example at issue, the active layer 110 has a dopant concentration ranging from 10¹⁵ ions/cm³ to 10¹⁶ ions/cm³. Typically, the substrate 105 has a thickness ranging from 1 μm to 5 μm, for example from 2 μm to 3 μm (such as 3 μm); in power applications, the active layer 110 instead has a larger thickness, for example ranging from 5 μm to 20 μm, for example from 7 μm to 19 μm (such as 17 μm).

An isolation layer 305 (for example, of field oxide) is formed on each chip in order to cover the front surface 120 except for a portion thereof where functional regions of the desired electronic components, such as the drain region 135 and the contact regions 225, are defined (by implanting doping impurities into the active layer 110). In particular, the isolation layer 305 may be obtained by means of the conventional LOCOS (Local Oxidation of Silicon) technique; alternatively, other techniques, such as the STI (Shallow Trench Isolation) technique may be used.

Moving to FIG. 3B, multiple trenches 210 are formed, by selectively etching the isolation layer 305 and the active layer 110; for example, the figure shows three trenches 210 (each one with a square cross section). In order to form the trenches 210, a photoresist or hard mask 310 is provided on top of the isolation layer 305 and the free portion of the front surface 120, so as to leave exposed areas thereof where the trenches 210 are desired. Alternatively, the same trenches may also be formed by operating directly on the active layer 110 (without any field oxide layer).

In the example at issue, a trench depth Td (measured from the front surface 120) is lower than the thickness of the active layer 110. In particular, the trench depth Td ranges from 5 μm to 17 μm, for example from 6 μm to 16 μm, such as 114 μm. In this way, the trenches 210 do not reach the substrate 105, but they rest at a distance d from the substrate 105 equal to the difference between the thickness of the active layer 110 and the trench depth Td (a few μm in the example at issue), This allows maintaining the size of the trenches 210 as small as possible; at the same time, the resulting surrounding region (being formed both around and below the trenches 210) is exploited as discussed below. Moreover, this allows avoiding any etching in the (heavily doped) substrate 105, so as to minimize the introduction of any dislocation defects.

The trenches 210 are very narrow and deep. A form ratio between the trench depth Td and a trench width I (defined by the side of its square cross-section in the example at issue) may range from 2 to 20, for example from 2.5 to 19 (such as, 17.5). For example, the trench width I ranges from 0.5 μm to 2 μm, such as from 0.7 μm to 1.8 μm (such as 0.8 μm). Typically, each trench 210 is spaced apart from any adjacent trench 210 by a distance s—measured between their lateral surfaces—which may range from 1 μm to 0.5 μm, for example from 1.1 μm to 1.3 μm (such as 1.2 μm). This layout of the trenches 210 has been found to provide good results (in terms of the reduction of the latch-up and the guard region size), while keeping the process complexity (in term of morphological structures) in a safe region.

As shown in FIG. 3C, an Implantation of doping impurities is performed in order to form (Within the active layer 110) highly implanted doped regions 315, which are adjacent to the corresponding trenches 210. Such implantation process uses the mask 310 in order to have the implanted regions 315 in areas corresponding to the trenches 210. The implanted regions 315 have an opposite type of conductivity with respect to the active layer 110. For example, in order to form implanted regions 315 of the N++type, Phosphorus (P) or Arsenic (As) doping ions may be used; the dose of the doping impurities may range from 10¹⁵ Atoms/cm² to 10¹⁶ Atoms/cm², with an implanting energy lower than 50 KeV, such as 25 KeV.

The desired result is achieved by multiple implantation processes along different directions, in order to cause the doping impurities to penetrate into the whole active layer 110 surrounding each trench 210. Particularly, at least two implantation processes may be performed along directions that are symmetric with respect to a vertical direction Y (parallel to the longitudinal axes of the trenches 210). In this way, the doping impurities are implanted through a portion of a lateral surface of the trenches 210 at each iteration of the implantation process (so as to reach a corresponding region of the active layer 110 around the trenches 210). A further implantation process may be performed substantially along the vertical direction Y; in this way, the doping impurities are implanted through a bottom surface of the trenches 210 (so as to reach a region of the active layer 10 below the trenches 210).

In particular, each one of the (lateral) implantation processes may involve the use of a beam of doping impurities propagating along a direction I having a corresponding tilt a with respect to the vertical direction Y In an embodiment, the tilt a should not exceed an arctg function of a ratio between the trench width I and the trench depth Td—i.e., α<=arctg(I/Td). This allows having the implanted doping impurities reach completely the lateral surface of each trench 210 without leaving non-doped semiconductor regions (thereby avoiding a so-called shadow-effect). The tilt α may range from 0.5° to 3.15°, for example from 0.6° to 3.10° (such as α=30). Conversely, during the (bottom) implantation process the tilt α is substantially 0°. For example, during a first implantation process, the wafer is inclined with respect to a direction of the doping impurities beam at an angle α=3°, whereas during a second implantation process the wafer is inclined at the opposite angle α=−3°, and finally during a third implantation process the wafer is not inclined (α=0°) In this case, it is possible to obtain trenches 210 with a form ratio up to Td/I<=1/tg(α)=1/tg(3°)=19.08.

Referring to FIG. 3D, a layer of conductive material 215 is deposited so as to completely fill the trenches 210.

In an embodiment of the present invention, the conductive material 215 comprises a polysilicon layer being doped with impurities of the N+ type. In particular, the doped polysilicon layer may be obtained by forming a polysilicon layer doped in situ with phosphine (PH₃)—for example, by means of Low-Pressure Chemical Vapor Deposition.

As shown in FIG. 3E, the excess conductive material 215 is removed so as to be flush with the isolation layer 305. For example, this result may be achieved by means of the CMP (Chemical Mechanical Polishing) technique, in case the free surface of the conductive material 215 exhibits negligible roughness (for example, lower than 100 nm). Vice versa, in case the free surface of the conductive material 215 exhibits significant roughness (such as higher than 100 nm), a rough etching of the conductive material 215 may be previously performed (providing, on the filled trenches 210, an additional mask adapted to protect them from this etching process). In any case, the mask 310 (See FIG. 3D)—together with the above-mentioned additional mask when present—is then stripped away.

The chip is now subjected to a thermal activation process at a temperature that ranges for example from 950° C. to 1,050° C., such as from 980° C. to 1,030° C. (for example, 1,000° C.) the activation process lasts for a period that ranges, for example, from 60 s to 1,800 s, such as 120 s to 1,500 s (for example, 300 s). During this phase, the chip is heated shortly (for example, by means of a Rapid Thermal Process or of a Rapid Thermal Annealing) up to the activation temperature and subsequently cooled slowly. This process is used for activating the doping impurities previously implanted both in the regions 115,135 (used for implementing the electronic components of the device) and in the regions 315,225 (used for implementing the guard region).

As shown in FIG. 3F, this activation process results in the generation of a surrounding region 220. As can be seen, the (activated) doping impurities reach the substrate 105 thanks to their deep implantation through the trenches 210 (even if no diffusion is performed). Particularly, the doping impurities associated with the different trenches 210 enters in contact so as to form a single surrounding region 220 (extending from the front surface 120), which embeds all the filled trenches 210 and reaches the substrate 105. This configuration may provide the best performance of the resulting guard region 205 (in terms of the efficiency in reducing the latch-up and of its size). In particular, the use of multiple filled trenches 210 reduces the resistance of the guard region 205 (for the same size); indeed, in this case it is possible to implant more doping impurities so as to obtain a larger surrounding region 220 (more conductive than the filled trenches 210).

Moving to FIG. 3G, a dielectric layer 320 (for example, of silicon oxide nitride) is deposited on top of the isolation layer 305 and on the free surface of the filled trenches 210 (for example, by means of a CVD process). A plurality of contact windows 325 are etched in the dielectric layer 320 so as to reach the filled trenches 210 (at the same time, other windows are opened to reach the regions 115, 135 and 225).

Afterwards, a metallization layer 330 (for example, Al or Ti/TiN plus a W-plug and an Al layer) is deposited on top of the chip, thereby filling the contact windows 325. The metallization layer 330 is then shaped to define the conductive path 230 which short-circuits the guard region 205 to the contact regions 225 (and then to the active layer 110); at the same time, interconnection taps are formed to contact the functional regions, such as the semiconductor region 135. In this way, no further etching through the isolation layer 305 is required to contact the guard region 205 (since the filled trenches 210 are already exposed). Alternatively, when the trenches are formed directly in the active layer 110 without any field oxide layer (as pointed out above), the conductive path 230 and the taps may also be made with self aligned silicide, so as to further reduce their area occupation.

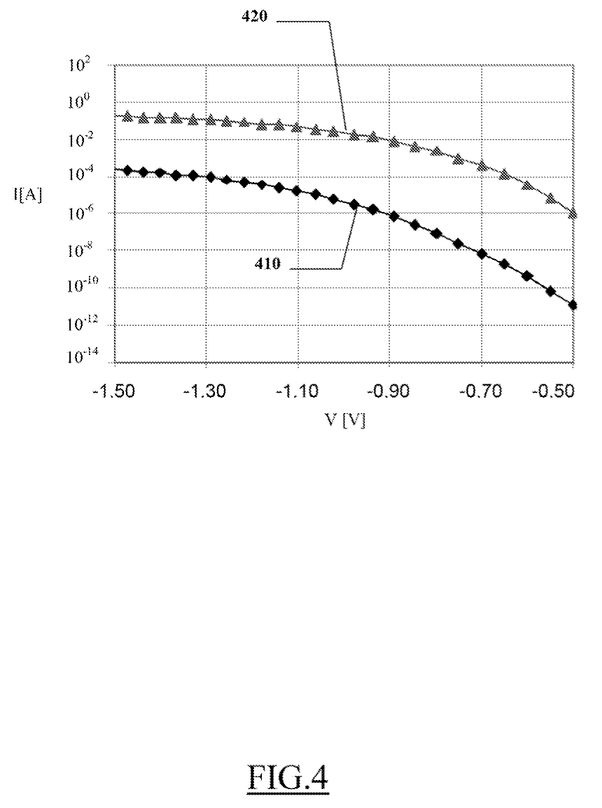

Referring to FIG. 4, there are illustrated simulated working characteristics of the electronic device according to an embodiment of the present invention when compared to conventional electronic devices without any additional guard region.

In particular, the FIG. 4 provides diagrams, which have a collector current I[A] of the parasitic NPN BJT on an axis of ordinates (in an exponential scale) and an emitter voltage V[V] thereof on an axis of abscissas (in a linear scale).

For obtaining these working characteristics, the substrate is biased to the ground voltage and the voltage V (ranging from −1.5V to −0.50V) is applied to the emitter region of the NPN BJT; the corresponding collector current I flowing trough the parasitic NPN BJT is then measured.

In detail, a working characteristic 410 is obtained when the guard region is added between the collector region and the emitter region of the parasitic NPN BJ. The other working characteristic 420 is obtained for an electronic device lacking this guard region.

As it can be noted, the working characteristic 410 is below the working characteristic 420 (meaning that the collector current I flowing trough the base region of the parasitic NPN BJT in an electronic device according to the proposed embodiment of the present invention is significantly lower than it is in conventional electronic devices). For example, when the voltage V is equal to −1V, the collector current I is reduced by approximately four orders of magnitude (from 10⁻¹ A to 10⁻⁵ A).

The diagram of the FIG. 4 confirms that, by using the guard region according to an embodiment of present invention, a current gain of the parasitic NPN BJT is strongly reduced. In this ways it is possible to have the above-mentioned condition β_{N}*β_{P}>1 not satisfied, so as to inhibit the switching on of the parasitic SCR (thereby reducing the latch-up).

Naturally, in order to satisfy local and specific requirements, a person skilled in the art may apply to the solution described above many logical and/or physical modifications and alterations. More specifically, although the present invention has been described with a certain degree of particularity with reference to one or more embodiment(s) thereof it should be understood that various omissions, substitutions and changes in the form and details as well as other embodiments are possible. Particularly, the proposed embodiment(s) may even be practiced without the specific details (such as the numerical examples) set forth in the preceding description to provide a more thorough understanding thereof; conversely, well-known features may have been omitted or simplified in order not to obscure the description with unnecessary particulars. Moreover, it is expressly intended that specific elements and/or method steps described in connection with any disclosed embodiment of the invention may be incorporated in any other embodiment as a matter of general design choice.

For example, it is emphasized that the described process is not to be interpreted in a limitative manner. Particularly, it is possible to use equivalent steps, to remove some steps being not essential, or to add further optional steps; moreover, the masks used during the process can be different in number and in type.

Although in the preceding description reference has been made to a semiconductor substrate and an active layer of P-type, the conductivity types of these layers may be reversed (i.e., of N-type) or in any other combination. In any case, the numerical examples of the dopant concentrations should not be interpreted in a limitative manner.

Moreover, similar considerations apply if the device has an equivalent structure (such as with layers having different thickness or made with other materials).

Moreover, the active layer may have either a single layer or a multi-layer structure. Likewise, the trenches may have any other shape (for example, with a circular cross-section). Likewise, the guard region may have any other arrangement (for example, in the form of a frame, a strip, and the like).

In any case, the use of a guard region of the same type of conductivity of the active region is not excluded.

It should be noted that in a different embodiment of the invention, the guard region may be connected to a distribution line providing the ground voltage or a power supply voltage (for example, 5V) of the device. Also in this case, the guard region acts as a collector region adapted to collect the current of the active layer so as to reduce the current gain of the parasitic NPN BJT.

Moreover, nothing prevents forming the conductive path for contacting the guard region on the surrounding region around the trench.

Although in the preceding description reference has been made to a trench depth lower than the depth of the active layer, nothing prevents that in alternative embodiments of the present invention the trenches should reach the substrate, in such case, it may also be possible to avoid implanting the doping impurities through the bottom surface of the trenches.

Alternatively, the guard region may be formed with another number of trenches (down to a single one), moreover two or more guard regions (each one including one or more trenches) may be formed.

Moreover, nothing prevents using a different number of implantation processes (down to single one) each one with a doping impurities beam that forms a different angle with the axis of each trench; in any case, it is also possible that the doping impurities are not implanted through the whole lateral surface of the trench.

Likewise, the doping impurities may be activated with equivalent techniques.

Similar considerations apply if the steps of annealing are carried out at different temperatures and/or in different periods.

The proposed dimensioning of the trench depth, distance among the trenches and trench width should not be interpreted in a limitative manner, for example, the use of closer trenches may be possible.

In any case, each trench may be filled with different conductive materials (for example, directly with polysilicon already doped).

More generally, an embodiment may be implemented in whatever electronic device (even not of the CMOS type) that is integrated in a generic chip wherein it is desired to reduce the latch-up.

More generally, an embodiment leads itself to be applied even in electronic circuits that are not of power type.

The possibility of activating the dopant impurities for the electronic components and the guard region in different process phases exists.

Moreover, the reference to the smart power applications is merely illustrative, with the same solution that may be used in whatever application (for example, in a device including only power electronic components).

It should be readily apparent that the proposed device may be part of the design of an integrated circuit. The design may also be created in a programming language; moreover, if the designer does not fabricate chips or masks, the design may be transmitted by physical means to others. In any case, the resulting integrated circuit may be distributed by its manufacturer in raw wafer form, as a bare die, or in packages form. Moreover, the device may be integrated with other circuits in the same chip, or it may be mounted in intermediate products (such as mother boards) and coupled to other chips (such as a microprocessor or a memory). In any case, the integrated circuit is suitable to be used in complex systems (such as computers).

What is claimed is:

1. A method for reducing a latch-up phenomenon in an electronic device being integrated in a semiconductor chip having an exposed surface, the chip including at least one parasitic lateral bipolar transistor having a base region, wherein the method includes the step of:
forming a guard region extending from the exposed surface into the base region of each parasitic lateral bipolar transistor,
wherein forming the guard region includes:
forming at least one trench extending from the exposed surface into the base region, each trench having a lateral surface and a bottom surface;
implanting doping impurities into the chip through at least part of the lateral surface of each trench;
filling the at least one trench with conductive material; and
activating the implanted doping impurities to obtain at least one surrounding region around each trench.

2. The method according to claim 1, wherein the base region and the guard region are of opposite type of conductivity.

3. The method according to claim 1, wherein the method further includes:
forming a conductive path for short-circuiting the base region with the guard region.

4. The method according to claim 3, wherein the step of forming the conductive path includes:
contacting the at least one filled trench on a free surface thereof.

5. The method according to claim 1, wherein the step of implanting includes:
implanting the doping impurities into the chip further through the bottom surface of each trench.

6. The method according to claim 1, wherein the step of forming the at least one trench includes:
forming at least two trenches, the at least one surrounding region consisting of a single surrounding region embedding the trenches.

7. The method according to claim 1, wherein the step of implanting includes:
applying at least one beam of said doping impurities along a direction forming an angle with an axis of symmetry of each trench ranging from 0° to the arctg function of a ratio between a trench width and a trench depth, said axis of symmetry being perpendicular to the exposed surface.

8. The method according to claim 1, wherein the step of activating the doping impurities includes,
annealing the chip.

9. The method according to claim 8, wherein the step of annealing includes,
heating the chip at a temperature ranging from approximately 950° C. to 1,050° C. for a period ranging from approximately 60 s to 1,800 s.

10. The method according to claim 1, wherein a trench depth is higher than a trench width.

11. The method according to claim 10, wherein a form ratio between the trench depth and the trench width ranges from approximately 2 to 20.

12. The method according to claim 6, wherein a trench width ranges from 0.8 μm to 1 μm, each pair of adjacent trenches being spaced apart by a distance ranging from approximately 1 μm to 1.4 μm.

13. The method according to claim 1 wherein the step of filling the at least one trench includes:
filling the at least one trench with polysilicon, and
doping the polysilicon in situ.

14. The method according to claim 1A wherein the chip includes a substrate of a first type of conductivity, an active layer of the first type of conductivity being stacked on the substrate, a free surface of the active layer opposed to the substrate defining the exposed surface, and at least one pair of a first operative region and a second operative region of a second type of conductivity extending into the active layer from the exposed surface, the base region of each parasitic lateral bipolar transistor being formed between the first operative region and the second operative region of a corresponding pair, and wherein each guard region reaches the substrate.

15. The method according to claim 14, wherein the electronic device includes at least one CMOS pair of a first MOS transistor and a second MOS transistor, the first MOS transistor including a well region of the second type of conductivity extending into the active layer from the exposed surface, a source region and a drain region of the first type of conductivity extending into the well region from the exposed surface, and the second MOS transistor including a source region and a drain region of the second type of conductivity extending into the active layer from the exposed surface, the step of forming the guard region including:
forming the guard region between the well region of the first MOS transistor and one of the source region and the drain region of the second MOS transistor.

16. The method according to claim 14, further including the step of:
forming at least one power component in the chip.

17. The method according to claim 16, wherein the step of forming the at least one power component includes:
implanting further doping impurities into the chip through corresponding selected regions of the exposed surface, and
activating the further doping impurities during the step of activating the doping impurities.

18. The method according to claim 16, further including the step of:
forming a logic circuit into the chip for controlling the at least one power component.

19. An integrated circuit, comprising:
a semiconductor layer of a first conductivity;
a well disposed in the layer and of a second conductivity;
a first source/drain region formed in the well and of the first conductivity;
a second source/drain region formed in the layer outside of the well and of the second conductivity; and
a guard region disposed in the layer between the well and the second source/drain region and of the second conductivity.

20. The integrated circuit of claim 19 wherein:
the first conductivity comprises P-type conductivity; and
the second conductivity comprises N-type conductivity.

21. The integrated circuit of claim 19 wherein:
the layer has a first doping concentration;
the well and the first and second source/drain regions have respective second, third, and fourth doping concentrations that are each greater than the first doping concentration; and
the guard region has a fifth doping concentration that is greater than each of the firsts second, third, and fourth doping concentrations.

22. The integrated circuit of claim 19 wherein the guard region comprises:
a trench having sides and a bottom;
a conductive material disposed in the trench; and
an outer region of the second conductivity and disposed adjacent to the sides and bottom of the trench.

23. The integrated circuit of claim 19 wherein the guard region comprises:
multiple trenches each having respective sides and a bottom;
a conductive material disposed in the trenches; and
an outer region of the second conductivity and disposed adjacent to the sides and bottoms of the trenches.

24. The integrated circuit of claim 19 wherein:
the layer has a depth; and
the guard region spans the entire depth of the layer.

25. The integrated circuit of claim 19 wherein the guard region surrounds the well.

26. The integrated circuit of claim 19 wherein the guard region surrounds the second source/drain region.

27. The integrated circuit of claim 19, further comprising:
a contact region disposed in the layer adjacent to the guard region and of the first conductivity; and
a conductor coupled between the guard region and the contact region.

28. The integrated circuit of claim 19, further comprising:
a contact region disposed in the layer adjacent to the guard region and of the first conductivity;
wherein the guard region comprises
a trench having sides and a bottom,
a conductive material disposed in the trench, and
an outer region having the second conductivity and disposed adjacent to the sides and bottom of the trench; and
a conductor coupled between the contact region and the conductive material in the trench.

29. The integrated circuit of claim 19, further comprising
a substrate of the first conductivity; and
wherein the layer is disposed over the substrate.

30. An integrated circuit, comprising:
a semiconductor layer of a first conductivity;
a silicon-controlled rectifier disposed in the layer and having an anode and a cathode, and
a guard region disposed in the layer between the anode and the cathode and of a second conductivity.

31. The integrated circuit of claim 30 wherein:
the first conductivity comprises P-type conductivity; and
the second conductivity comprises N-type conductivity.

32. The integrated circuit of claim 30 wherein the silicon-controlled rectifier comprises a parasitic silicon-controlled rectifier.

33. The integrated circuit of claim 30 wherein,
the anode and the cathode have respective first and second doping concentrations; and
the guard region has a third doping concentration that is greater than each of the first and second doping concentrations.

34. The integrated circuit of claim 30 wherein:
the layer has a first doping concentration; and
the guard region has a second doping concentration that is greater than the first doping concentration.

35. The integrated circuit of claim 30 wherein:
the layer has a depth; and
the guard region spans the entire depth of the layer.

36. The integrated circuit of claim 30 wherein the guard region surrounds the anode.

37. The integrated circuit of claim 30 wherein the guard region surrounds the cathode.

38. A system, comprising:
a first integrated circuit, comprising
a semiconductor layer of a first conductivity,
a well disposed in the layer and of a second conductivity,
a first source/drain region formed in the well and of the first conductivity,
a second source/drain region formed in the layer outside of the well and of the second conductivity, and
a guard region disposed in the layer between the well and the second source/drain region and of the second conductivity; and
a second integrated circuit coupled to the first integrated circuit.

39. The system of claim 38 wherein the first and second integrated circuits are disposed on a same die.

40. The system of claim 38 wherein the first and second integrated circuits are disposed on respective first and second dies.

41. The system of claim 38 wherein the second integrated circuit comprises a controller.

42. A system, comprising:
a first integrated circuit, comprising
a semiconductor layer of a first conductivity,
a silicon-controlled rectifier disposed in the layer and having an anode and a cathodes and
a guard region disposed in the layer between the anode and the cathode and of a second conductivity;
a second integrated circuit coupled to the first integrated circuit.

43. The system of claim 42 wherein the first and second integrated circuits are disposed on a same die.

44. The system of claim 42 wherein the first and second integrated circuits are disposed on respective first and second dies.

45. The system of claim 42 wherein the second integrated circuit comprises a controller.

46. A method, comprising:
forming in a semiconductor layer of a first conductivity first and second regions of a second conductivity;
forming in the first region a third region of the first conductivity; and
forming in the layer between the first and second regions a guard region of the second conductivity.

47. The method of claim 46 wherein;
one of the first and second regions comprises a well;
the other of the first and second regions comprises a first source/drain region; and
the third region comprises a second source/drain region.

48. The method of claim 46 wherein forming the guard region comprises:
forming in the layer a trench between the first and second regions;
implanting a dopant of the second conductivity into at least one of the sides and bottom of the trench; and
filling the trench with a conductive material after implanting the dopant.

49. The method of claim 46 wherein forming the guard region comprises:
forming in the layer a trench between the first and second regions;
implanting a dopant of the second conductivity into at least one of the sides of the trench at an angle relative to a center axis of the trench; and
filling the trench with a conductive material after implanting the dopant.

50. The method of claim 46, further comprising forming the semiconductor layer over a substrate.
